(19) United States
(12) Patent Application Publication
(10) Pub. No.: US 2011/0073151 A1
(43) Pub. Date: Mar. 31, 2011

(54) SOLAR CELL MODULE

(75) Inventor: Haruo YAGO, Ashigara-kami-gun (JP)

(73) Assignee: FUJIFILM CORPORATION, Tokyo (JP)

(21) Appl. No.: 12/845,435

(22) Filed: Jul. 28, 2010

(30) Foreign Application Priority Data
Sep. 29, 2009 (JP) 2009-224761

(51) Int. Cl. H01L 31/042

(52) U.S. Cl. 136/244

(57) ABSTRACT

A solar cell module includes a metal substrate, an insulation layer, series-connected solar cells, two output terminals, and a ground terminal. Each solar cell includes an underside electrode layer, a photoelectric conversion layer and a transparent electrode layer. The solar cell module further includes an electrical conductive layer for electrically connecting the metal substrate to the underside electrode of one grounding solar cell located in a range of plus 10% to minus 10% of the number of the solar cells from a solar cell located at a center of the line of the solar cells. The ground terminal is connected through the metal substrate and the conductive layer to the grounding solar cell.

### BACKGROUND OF THE INVENTION

The present invention relates to a solar cell module and particularly to a thin-film solar cell module.

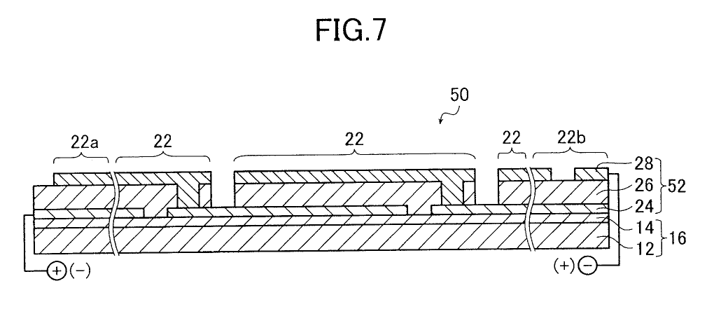

The solar batteries have now entered a phase of wide use, and there have been proposed a variety of solar cell modules as component parts of a solar battery system. FIG. 7 illustrates a conventional integrated thin-film solar cell module that is receiving particular attention among those currently proposed.

A solar cell module 50 illustrated in FIG. 7 is an integrated thin-film solar cell module where a number of layered solar cells (photoelectric conversion elements) 22, each formed of a photoelectric conversion layer 26 made of a semiconductor that generates electric current upon light absorption and sandwiched by an underside electrode (lower electrode) 24 and a transparent electrode (upper electrode) 28, are connected in series to form an electric power generation layer 52 on a support substrate 16, which is composed of a metal substrate 12 and an insulation layer 14 formed thereon, i.e., a metal plate having an insulation layer. As illustrated in FIG. 7, a lead (lead wire) is connected to the underside electrode 24 of a solar cell 22 located at one end of the numerous series-connected solar cells 22 of the solar cell module 50 and a lead is also connected to the transparent electrode 28 of a solar cell 22 located at the other end to harvest electric power from the outside. Although the underside electrode 24 is a positive terminal and the transparent electrode 28 is a negative terminal in the illustrated example of the solar cell module 50, the polarity may be reversed depending upon the kind of the photoelectric conversion layer 26, so that the underside electrode 24 is a negative terminal and the transparent electrode 28 is a positive terminal. The positive terminal and the negative terminal of the solar cell module 50 are respectively connected through leads to, for example, the positive terminal and the negative terminal of an inverter described later. The direct current output from the solar cell module 50 is converted into alternating current for use by users such as a factory, a business office and a residence.

Meanwhile, development and propositions are being made to translate the solar cell modules into practical use for residential solar battery systems. Among such propositions are those for achieving interconnected operation of solar batteries, which generate direct current, and an alternating current electricity system such as a commercial alternating current electricity system. See JP 11-252803 A and JP 10-322885 A. Using a solar battery in interconnected operation with an alternating current electricity system requires observation of the Grid-interconnection Code.

JP 11-252803 A describes a solar photovoltaic power generation system comprising a solar cell array formed by solar cell modules connected in series and in parallel, an uninsulated inverter for converting the direct current output of the solar cell array into alternating current for enabling interconnected operation with a commercial alternating current electricity system, and a system interconnection switch and a ground fault interrupter connected to a point between the alternating current output of that inverter and the commercial alternating current electricity system, wherein the inverter contains potential fixing means for fixing the potential on the side of the system interconnection switch closer to the solar cell array to a given potential at least when the system interconnection switch is open.

Although the alternating current output of the uninsulated inverter, which is used as an interconnection inverter for establishing interconnection with a commercial alternating current electricity system, is directly connected to user loads such as, for example, on-premises loads of a factory, a business office, etc. and a residence load, a commercial alternating current electricity system is connected to the on-premises loads through an interconnection switch and a circuit breaker having an earth leakage breaker function (earth leakage breaker) composed of a ground fault interrupter to completely separate the commercial alternating current electricity system from the user load in case of, for example, on-premises leakage, resulting in electricity failure.

JP 11-252803 A describes a solar cell array composed of solar cell modules connected in series and in parallel as solar panels integrated with the roof structure that can be used for not only a building on the premises of a factory, a business office, and the like but also housing in general such as a residence. Such a solar cell module uses a metal plate as a reinforcement plate, which may be used as construction material such as a roof structure material and a wall material, and has solar cell elements sealed by a filler resin on the metal plate. Thus, it is a solar cell module of a type integrated with the roof structure material.

When such a solar cell array is used with an uninsulated inverter, a nonnegligible stray capacitance is generated between the solar cell array and the ground because the solar cell array is installed outdoors over a relatively large area as a rooftop or the like. Closing the system interconnection switch can therefore trigger flow of a feeble leak current due to the stray capacitance, thereby generating leak current pulse, which may cause the earth leakage breaker to operate unnecessarily. JP 11-252803 A prevents the earth leakage breaker from tripping upon closing the system interconnection switch by providing potential fixing means in the inverter to ensure that, prior to closing the system interconnection switch, the potential on the side of that switch closer to the solar cell array is fixed to a given potential by means of the system interconnection switch or, more specifically, to ensure that the midpoint potential of the commercial alternating current electricity system and the midpoint potential of the voltage of the direct current electricity of the solar cell array after the direct current voltage is increased by the uninsulated inverter are an equal potential, which may for example be the ground potential. Thus, JP 11-252803 A consider fixing the potential of the solar cell array in order to fix the stray capacitance of the solar cell array, hence the stray capacitance and potential difference between the metal plate and the solar cell elements.

JP 10-322885 A describes that in a solar photovoltaic power generation system comprising a solar cell array, an uninsulated inverter, and a ground fault interrupter provided between the uninsulated inverter and a load and between an electricity system and a load, establishing a relationship Ca<EL/3 between the stray capacitance Ca (μF) of the solar battery and the rated sensed current EL (mA) of the ground fault, in lieu of providing the potential fixing means as in JP 11-252803 A, purportedly can ensure that the leak current due to the stray capacitance of the solar battery can be held within a dead region of the ground fault interrupters, that unwanted operations of the ground fault interrupters can be prevented, and that electric power outage in a user's facilities such as a building of a factory, a business office, etc. on the user's premises or the user's residential house and a resultant unwanted interruption of operation of the solar voltaic generation system can be prevented, thereby preventing loss of generated electric power.

### SUMMARY OF THE INVENTION

In the case of the conventional solar cell module 50 illustrated in FIG. 7, when the number of series-connected solar cells 22 is increased to increase the output voltage per module, a maximum voltage between the metal substrate 12 and the underside electrode 24 of the electric power generation layer 52 will be equivalent to the output voltage per module. This necessitates increasing the withstand voltage of the insulation layer 14 between the metal substrate 12 and the underside electrode 24 of the electric power generation layer 52. However, due to a limit to the withstand voltage of the insulation layer 14, the output voltage per module could not be increased significantly.

Further, although the solar photovoltaic power generation system disclosed in JP 11-252803 A may eliminate the possibility of the ground fault interrupter performing unwanted operations upon closing the system interconnection switch, the system additionally requires the potential fixing means to that end, say in the inverter, necessitating a supply of electric power to operate the potential fixing means, which consumes the electric power generated by the solar cells. In addition, operation of the potential fixing means continues to consume the electric power generated by the solar battery after the system interconnection is started. JP 11-252803 A describes providing the potential fixing means with switching devices and turning on and off the switching devices in conjunction with the system interconnection switch as it is closed and opened in order to eliminate power consumption by the potential fixing means after the system interconnection is started. However, elimination of power consumption by the potential fixing means was impossible when the system interconnection switch is open, and, furthermore, switching devices needed to be provided in addition to the potential fixing means.

Although the solar photovoltaic power generation system described in JP 10-322885 A, as in the case of the system described in JP 11-252803 A, eliminated the problem of the unwanted operations performed by the ground fault interrupter upon closing the system interconnection switch, the stray capacitance of the solar battery needed to be curbed according to the sensitivity of the ground fault interrupter, and the number of solar panels that can be used was limited, whereas increasing the usable number of solar panels would necessitate lowering of the sensitivity of the ground fault interrupter in order to detect only a large leak current but excessively lowering the sensitivity was dangerous because electric leak in the user load could not be detected.

A first object of the invention is to eliminate the above problems associated with the prior art and provide high-voltage solar cell modules wherein the adverse effects produced by stray capacitance between the electric power generation layer of the solar cells and the metal substrate is minimized, and wherein the potential difference between them is so small that the withstand voltage of the insulation layer between the electric power generation layer and the metal substrate need not be increased, achieving an increased output voltage per module.

A second object of the invention is to provide a solar cell module that permits interconnected operation with an alternating current electricity system such as a commercial alternating current electricity system by using an uninsulated inverter such as an inexpensive transformerless inverter without additionally requiring such components as potential fixing means and switching devices, and without requiring a circuit breaker, such as a ground fault interrupter, having a specially low sensitivity, and which permits construction of a solar photovoltaic power generation system capable of producing a high-voltage output owing to the solar cell module that may be used in an unlimited number as a unit solar battery.

To achieve the first and the second objects described above, the solar cell module of the invention comprises a metal substrate, an insulation layer formed on the metal substrate, series-connected solar cells formed on the insulation layer, two output terminals provided on both ends of the solar cells, and a grounding terminal connected to a central portion of the solar cells, wherein each of said solar cells comprise an underside electrode formed on the insulation layer, a photoelectric conversion layer provided on the underside electrode to convert received light into electricity, and a transparent electrode layer formed on the photoelectric conversion layer, and wherein said transparent electrode layer of each of the solar cells is connected to the underside electrodes of adjacent solar cell to connect the solar cells in series, and wherein said two output terminals are each composed of a first output terminal connected to the underside electrode of a solar cell at one end of the solar cells and a second output terminal connected to the underside electrode of a solar cell at the other end of the solar cells, and wherein said solar cell module further comprises an electrical conductive layer provided to electrically connect the metal substrate to the underside electrode of one grounding solar cell located in a position in a range of from plus 10% to minus 10% of the number of the solar cells from a solar cell located at a center of the solar cells, and wherein said ground terminal is connected to the metal substrate and further connected through the metal substrate and the conductive layer to the grounding solar cell.

The grounding solar cell is preferably a solar cell located in a position in a range of from plus 5% to minus 5% of the number of the solar cells from the solar cell located at the center and is more preferably a solar cell located at the center.

The conductive layer is preferably a part of the insulation layer where insulation has broken down and which is rendered electrically conductive by subjecting the part of the insulation layer on the metal substrate of the grounding solar cell to thermal ultrasonic treatment to achieve electrical breakdown in the part of the insulation layer, more preferably a part of the insulation layer where insulation has broken down and which is rendered electrically conductive by forming at least the underside electrode on the insulation layer on the metal substrate to at least partially form the grounding solar cell, applying ultrasonic solder to the grounding solar cell at least partially formed and then subjecting to thermal ultrasonic treatment the part of the insulation layer on the metal substrate of the grounding solar cell at least partially formed where the ultrasonic solder has been applied to achieve electrical breakdown in the part of the insulation layer and still more preferably a part of the insulation layer where insulation has broken down and which is rendered electrically conductive by forming the solar cells, applying ultrasonic solder to the grounding solar cell and then subjecting to thermal ultrasonic treatment the part of the insulation layer on the metal substrate of the grounding solar cell where the ultrasonic solder has been applied to achieve electrical breakdown in the part of the insulation layer.

Alternatively, the conductive layer is preferably the underside electrode layer of the grounding solar cell formed on an exposed part of the metal substrate by forming the insulation layer on the metal substrate, removing a part of the insulation layer corresponding to the grounding solar cell to expose the metal substrate, and then forming the underside electrode on the insulation layer and the exposed part of the metal substrate.

The solar cells are preferably separated each other by linear grooves and each of the solar cells are formed into a linear form on the insulation layer on the metal substrate, and wherein the underside electrode, the photoelectric conversion layer, the transparent electrode layer, and the conductive layer have a linear shape.

The solar cells are preferably integrated thin-film solar cells.

The solar cells preferably comprise one kind of thin-film solar cells selected from the group consisting of CIS based thin-film solar cells, CIGS based thin-film solar cells, silicon-based thin-film solar cells, CdTe based thin-film solar cells, III-V group based thin-film solar cells, dye-sensitized thin-film solar cells, and organic thin-film solar cells.

The photoelectric conversion layer preferably comprises as a major component at least one kind of a compound semiconductor having chalcopyrite structure, more preferably comprises as a major component at least one kind of compound semiconductor containing an Ib group element, a IIIb group element, and a VIb group element, and still more preferably comprises as a major component at least one kind of compound semiconductor containing at least one kind of Ib group element selected from the group consisting of Cu and Ag, at least one kind of IIIb group element selected from the group consisting of Al, Ga, and In, and at least one kind of VIb group element selected from the group consisting of S, Se, and Te.

The metal substrate having the insulation layer formed thereon is preferably formed of an anodized aluminum substrate, and the insulation layer is an anodized film, and the aluminum substrate is preferably a composite aluminum substrate made of a composite material and preferably a clad sheet formed of a steel sheet sandwiched by two aluminum sheets or a clad sheet formed of a stainless steel sheet and an aluminum sheet.

The present invention permits minimizing the adverse effects produced by the stray capacitance generated between the electric power generation layer of the solar cells and the metal substrate, minimizing the potential difference between them, eliminating the need to increase the withstand voltage of the insulation layer between the electric power generation layer and the metal substrate, and increasing the output voltage per module. As a result, the present invention enables a high-voltage solar cell module to be obtained.

Further, the present invention permits construction of a solar photovoltaic power generation system for interconnected operation with an alternating current electricity system such as a commercial alternating current electricity system by using an uninsulated inverter such as an inexpensive transformerless inverter without requiring such components as potential fixing means and switching devices, and without requiring a circuit breaker, such as a ground fault interrupter, having an especially low sensitivity, the solar photovoltaic power generation system being capable of producing a high-voltage output owing to the solar cell module that may be used in an unlimited number as a unit solar battery.

### BRIEF DESCRIPTION OF THE INVENTION

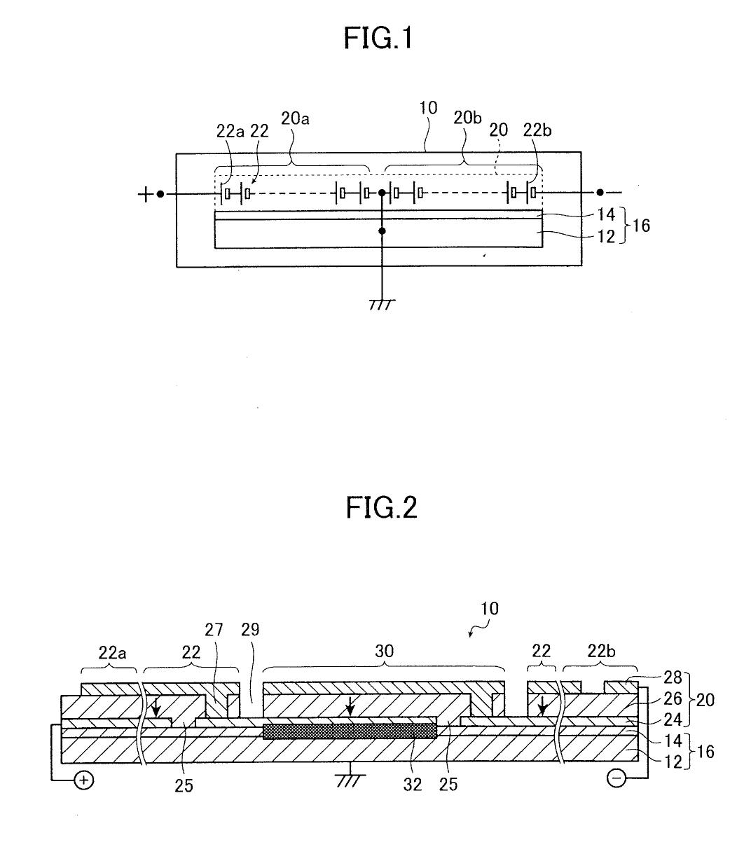

FIG. 1 is a view of a circuit configuration schematically illustrating an example of solar cell module according to the invention.

FIG. 2 is a cross section schematically illustrating a first embodiment of the solar cell module of FIG. 1.

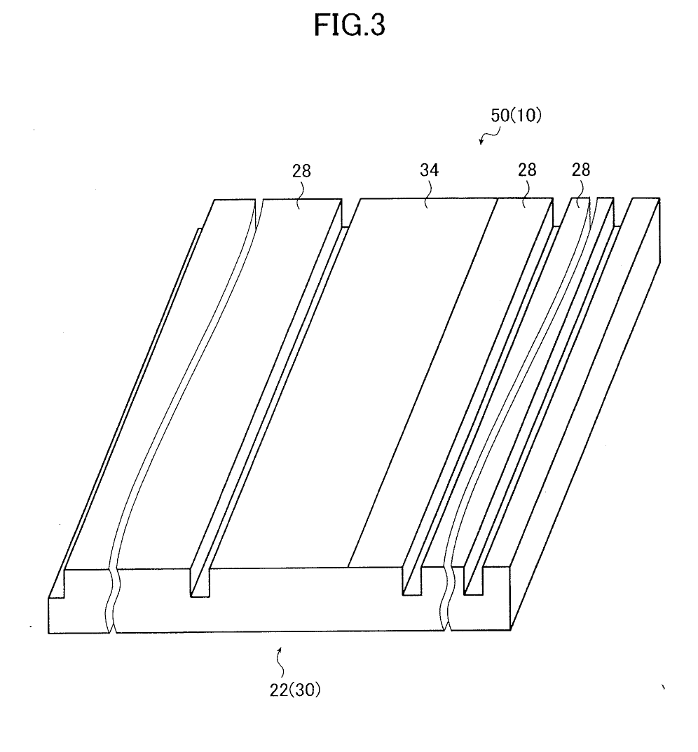

FIG. 3 is a perspective view of a solar cell module in the process of manufacture for explaining an example of a process of manufacturing the solar cell module illustrated in FIG. 2.

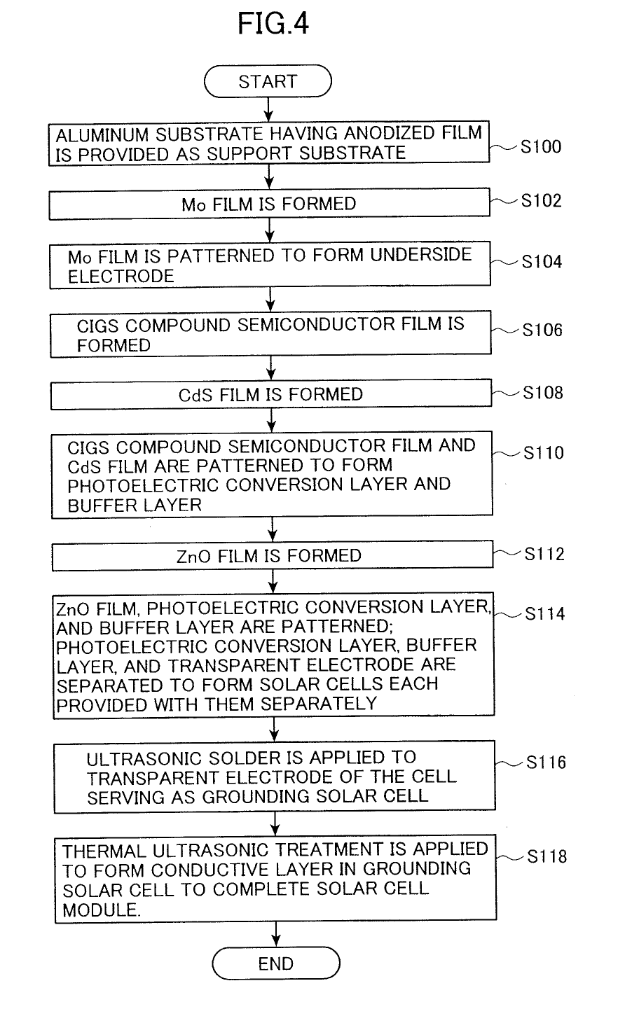

FIG. 4 is a flow chart showing an example of method for manufacturing the solar cell module illustrated in FIG. 2.

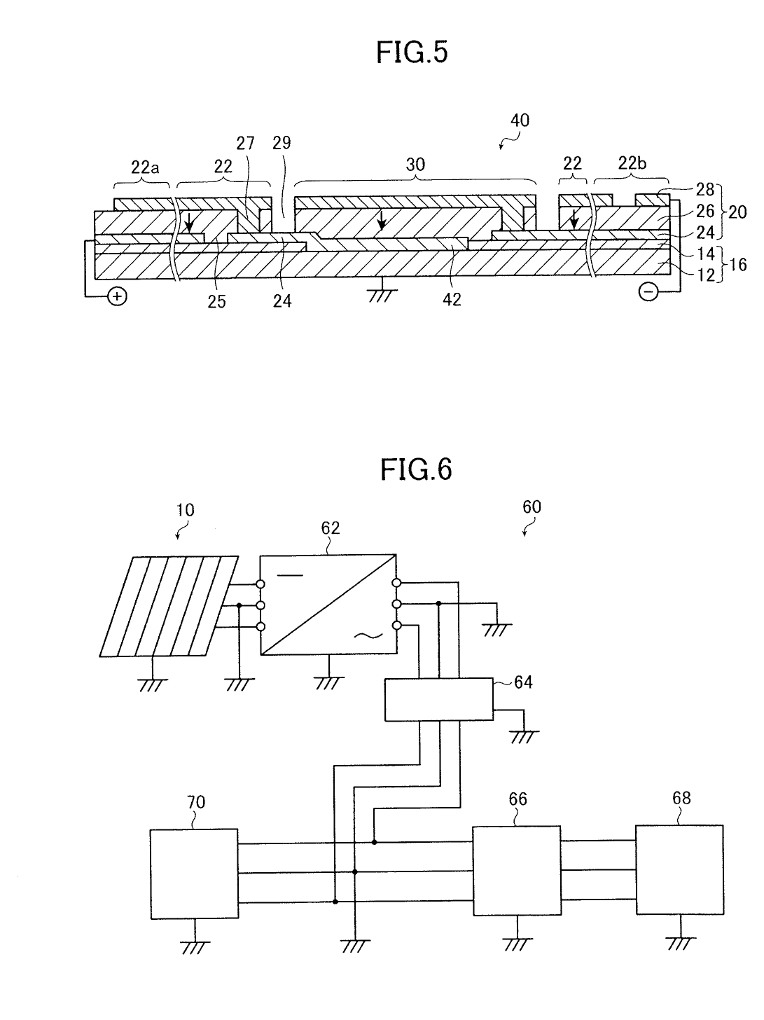

FIG. 5 is a cross section schematically illustrating a second embodiment of the solar cell module illustrated in FIG. 1.

FIG. 6 is a view schematically illustrating an example of configuration of a solar photovoltaic system using solar cell modules of the invention.

FIG. 7 is a schematic cross section illustrating a conventional solar cell module.

### DETAILED DESCRIPTION OF THE INVENTION

The solar cell modules according to the invention will be described in detail based upon preferred embodiments referring to the attached drawings.

FIG. 1 is a view of a circuit configuration schematically illustrating an example of solar cell module according to the invention. FIG. 2 is a cross section schematically illustrating a first embodiment of the solar cell module of FIG. 1.

As illustrated in FIG. 1, a solar cell module 10 according to the invention comprises, for example, a support substrate 16 including a grounded, substantially rectangular metal substrate 12 and an electric insulation layer 14 formed on the metal substrate 12 and a power generation layer 20 including series-connected solar cells 22 formed on the insulation layer 14.

In the solar cell module 10 of the invention, the positive polarity (plus) side of a solar cell 22a located at one end of the solar cells 22 in the power generation layer 20, used as a positive terminal, is connected to the positive terminal of a connection box, not shown, through a ribbon cable, not shown, while the negative polarity (minus) side of the solar cell 22b located at the other end, used as a negative terminal, is connected to the negative terminal of the connection box, not shown, through the ribbon cable, not shown, whereas the positive or negative polarity side of the centrally located solar cell 22 of the solar cells 22 or the positive or negative polarity side of one of the substantially centrally located solar cells 22, i.e., the two centrally located solar cells 22, is directly connected as a ground terminal to the metal substrate 12 of the support substrate 16 to ensure grounding.

In the solar cell module 10 of the invention, where, as illustrated in FIG. 1, the metal substrate 12 of the support substrate 16 is grounded and a grounding solar cell 30 (see FIGS. 2 and 4), whose positive or negative polarity is electrically connected directly to the metal substrate 12 of the support substrate 16, is grounded, the grounding solar cell 30 is most preferably the central solar cell 22 or a substantially centrally located solar cell 22 of the solar cells 22.

This ensures that the number of solar cells 22 located on one side of the middle of the solar cells through the solar cell 22a at the one extreme end, i.e., the number of solar cells 22 in the power generation layer 20a on the positive side agree or substantially agree with the number of solar cells through the solar cell 22b at the other extreme end, i.e., the number of solar cells 22 in the power generation layer 20b on the negative side. Thus, the number of solar cells can be halved as compared with the number of solar cells 22 in the power generation layer 52 in the conventional solar cell module 50, i.e., the number of solar cells 22 located between the solar cells 22a and 22b at both extreme ends, illustrated in FIG. 7, where the grounding solar cell 30 is not provided.

Thus, according to the illustrated example of the solar cell module 10, the potential difference (voltage) between the ground potential of the grounding solar cell 30 and the positive potential at the positive terminal of the solar cell 22a in the power generation layer 20a and the potential difference (voltage) between the ground potential of the grounding solar cell 30 and the negative potential at the negative terminal of the solar cell 22b in the power generation layer 20b can be equalized or substantially equalized. Thus, the potential difference can be halved as compared with the potential difference (voltage) between the solar cells 22a and 22b in the power generation layer 52 of the conventional solar cell module 50 illustrated in FIG. 7.

Therefore, with the solar cell module 10 where the voltage between the metal substrate 12 and the power generation layer 20 is half that between the metal substrate 12 and the power generation layer 52 in the conventional solar cell module 50 illustrated in FIG. 7, the withstand voltage required of the insulation layer 14 between the metal substrate 12 and the power generation layer 20 may be half that required in the case of the conventional solar cell module 50, and, hence, where an insulation layer 14 having the same withstand voltage is used, the potential difference (voltage) in the whole power generation layer 20, i.e., between the solar cells 22a and 22b can be doubled, permitting fabrication of a solar cell module having a doubled voltage.

Thus, the solar cell module 10 comprises a ground point that serves as a neutral point in the solar cells 22 in the power generation layer 20, and the adverse effects produced by the stray capacitance generated between the metal substrate 12 and the power generation layer 20 can be minimized while the output voltage per module can be increased, making the module 10 suitable for fabrication of a high-voltage solar cell module.

This configuration permits direct connection of the inverter and enables a configuration such that the ground or the neutral point of the alternating current output is equalized with the ground of the solar cell module 10 as will be described, which provides an advantage of permitting an easy connection of an inexpensive uninsulated transformerless inverter.

Although the solar cell module 10 illustrated in FIG. 1 is grounded (the position of the grounding solar cell 30 is located) at the center or at substantially the center of the arrayed solar cells 22 (at the solar cell 22 located in that position), the invention is not limited to that configuration; grounding may be established through a solar cell 22 located in a position in a range of plus or minus 10% from the center, i.e., in a range of from plus 10% to minus 10% from the center of the arrayed solar cells 22, the solar cell 22a at one extreme end and the solar cell 22b at the other extreme end being located at plus 100% and minus 100% from the center, respectively.

This is because grounding the solar cell module 10 even at a solar cell 22 located in a range of plus or minus 10% from the center of the arrayed solar cells 22 can, as in the above case, reduce the potential differences or voltages of the power generation layers 20 (20a, 20b) on both sides with respect to the ground potential to 55% or less of that in the conventional solar cell module 50 illustrated in FIG. 7, and reduce the voltage between the metal substrate 12 and the power generation layers 20, i.e., the withstand voltage of the insulation layer 14 between them, to 55% of that in the conventional solar cell module 50, and, where an insulation layer 14 having the same withstand voltage is used, the voltage of the whole power generation layer 20 can be increased 1.8-fold, and thus a solar cell module having a 1.8-fold voltage can be fabricated.

Also in this case, where, as in the above case, a ground point that serves as a neutral point is likewise provided among the solar cells 22 in the power generation layer 20, the adverse effects produced by the stray capacitance between the metal substrate 12 and the power generation layer 20 can be minimized as compared with the conventional solar cell module 50, making the solar cell module 10 suitable for fabrication of a high-voltage solar cell module.

When the solar cell module 10 has such a configuration and has directly connected thereto an inexpensive uninsulated inverter such as one without a transformer, the ground point or the neutral point of the alternating current output cannot completely coincide with the ground point of the solar cell module 10, but leak current due to the disparity between them is not so great that the circuit breaker such as an earth leakage breaker should perform unwanted operations as described earlier with reference to the prior art.

In other words, where an inexpensive uninsulated inverter such as one without a transformer is directly connected, the solar cell module 10 may be grounded in a position that may be located away from the center, provided that the circuit breaker such as an earth leakage breaker does not operate in an unwanted manner. Thus, the distance of the ground point from the middle may be determined according to the connected inverter, the circuit breaker such as a ground fault circuit interrupter, and the like.

For the reasons stated above, it is of course more preferable according to the invention to establish grounding through a solar cell 22 located plus or minus 5% from the center, or in a range from plus 5% to minus 5% from the center.

The support substrate 16 used in the illustrated example of the solar cell module 10 is a metal plate having an insulation layer comprising a metal substrate 12 and an insulation layer 14 formed thereon. The support substrate 16 is not specifically limited, provided that it is a metal plate equipped with an insulation layer, and is preferably a support substrate obtained by anodizing at least one side of an aluminum plate to form an anodized film as the insulation layer 14, the other side of the aluminum plate not subjected to anodization forming the metal plate 12.

The metal substrate 12 is not specifically limited, provided that it allows the insulation layer 14 to be formed and can support the power generation layer 20 when formed into the support substrate 16 that is a metal plate having an insulation layer. The metal substrate 12 is preferably an aluminum substrate at least one side of which is an aluminum layer and may be exemplified by an aluminum substrate and a composite aluminum substrate made of aluminum and another metal.

The thickness of the metal plate 12 may be selected as appropriate considering the overall strength required of the solar cell module 10 and preferably has a thickness in a range of 0.1 mm to 10 mm when formed into the support substrate 16 that is the metal plate having the insulation layer. When fabricating the support substrate 16 from an aluminum substrate, a composite aluminum substrate, etc., a thickness need to allow for reduction in thickness caused by anodization, washing prior to anodization, and grinding.

An aluminum substrate used in the invention may for example be a Class 1000 pure aluminum according to Japan Industrial Standard (JIS) or an alloy plate formed of aluminum and other metal elements exemplified by an Al—Mn alloy plate, an Al—Mg alloy plate, an Al—Mn—Mg alloy plate, an Al—Zr alloy plate, an Al—Si alloy plate, and an Al—Mg—Si alloy plate.

The composite aluminum substrate may be a clad sheet formed of an aluminum plate and a plate of another metal, such as a clad sheet formed of an aluminum plate and a stainless steel (SUS) plate, a clad sheet formed of a plate of any of a variety of steels sandwiched by two aluminum plates, and the like. According to the invention, a metal plate used with an aluminum plate to form a clad sheet may for example be one made of a steel such as mild steel, Invar alloy 42, Kovar alloy, or Invar alloy 36. Alternatively, the metal plate may be one permitting use as a roof material, a wall material, etc. for a residential house or a building to allow the solar cell modules of the invention to be used as a solar panel of a type that can be integrated with the roof material.

An aluminum plate, an aluminum alloy plate, etc. used for that purpose may contain a trace amount of a metal element such as Fe, Si, Mn, Cu, Mg, Cr, Zn, Bi, Ni, and Ti.

The insulation layer 14 formed on the metal substrate 12 is not specifically limited. Where the metal substrate 12 is an aluminum substrate or a composite aluminum substrate, the insulation layer 14 is preferably an anodized film formed on the metal substrate 12 by anodizing the aluminum substrate or the composite aluminum substrate. Anodization of an aluminum substrate or a composite aluminum substrate may be achieved by immersing the aluminum substrate or the composite aluminum substrate, acting as a positive electrode, together with a negative electrode in an electrolytic solution and applying a voltage between the positive and negative electrodes to complete electrolytic treatment.

The anodized film to serve as the insulation layer 14 may be formed on one side of an aluminum plate or the aluminum layer of a composite aluminum plate, i.e., the metal substrate 12 as described above. In the case of a clad sheet comprising an aluminum substrate or a clad sheet formed of a metal plate sandwiched by two aluminum plates, the anodized film is provided preferably on both sides of the aluminum layer to minimize warps and cracks produced in the anodized films caused by a difference in thermal expansion coefficient between the aluminum layer and the anodized film in, for example, the process of fabricating the power generation layer 20.

The thickness of the insulation layer 14 or the anodized film is not specifically limited, provided that the insulation layer 14 has insulation properties and a surface hardness sufficient to prevent, for example, damage that may be caused by a mechanical impact during handling. An excessive thickness thereof, however, may present problems from a viewpoint of flexibility. Therefore, the insulation layer 14 preferably has a thickness of 0.5 μm to 50 μm; the thickness can be controlled by electrolysis time as well as galvanostatic electrolysis and potentiostatic electrolysis.

Besides an anodized aluminum film, the insulation layer 14 may be one formed by producing any of various kinds of oxide layer such as an oxide glass layer containing any of such elements as Si, Ca, Zn, B, P, and Ti using any of various methods as appropriate such as vapor deposition and sol-gel processing.

The solar cell module 10 according to a first embodiment of the invention illustrated in FIG. 2 is a substrate type of solar cell module, wherein the power generation layer (photoelectric conversion device) 20 provided in the solar cell module 10 is an integrated thin film type. The power generation layer 20 comprises the grounding solar cell 30 formed on the insulation layer 14 of the support substrate 16 at the center thereof or substantially at the center thereof and the series-connected solar cells 22 on both sides of the grounding solar cell 30.

Like the solar cells 22 of the solar cell module 50 illustrated in FIG. 7, the solar cells 22 of the solar cell module 10 comprises the underside electrode 24 formed on the surface of the insulation layer 14 of the support substrate 16, the photoelectric conversion layer 26 formed on the underside electrode 24 to covert received light into electricity, and the transparent electrode 28 formed on the photoelectric conversion layer 26, so that the underside electrode 24, the photoelectric conversion layer 26, and the transparent electrode 28 are disposed on each other in this order on the insulation layer 14, the underside electrode 24 being closest to the insulation layer 14.

The grounding solar cell 30, an essential feature of the invention, comprises a conductive layer 32 formed of a part of the insulation layer 14 provided at the top of the support substrate 16 of the solar cells 22 so that, as in the case of the solar cells 22, the underside electrode 24, the photoelectric conversion layer 26, and the transparent electrode 28 are disposed on each other in this order on the conductive layer 32, the underside electrode 24 being closest to the conductive layer 32. The grounding solar cell 30 may or may not contribute to power generation, provided that the conductive layer 32 is formed to permit electric conduction between the underside electrode 24 and the metal substrate 12.

The solar cells 22 and the grounding solar cell 30 may comprise a buffer layer, not shown in FIG. 2, on the photoelectric conversion layer 26 so that the underside electrode 24, the photoelectric conversion layer 26, the buffer layer, and the transparent electrode 28 are disposed in this order.

In the solar cells 22, the underside electrodes 24 are formed on the surface of the insulation layer 14 so that each of them extends from a region on an end side (a part thereof on the right side in the drawing) of an adjacent solar cell 22 or the grounding solar cell 30 (located on the left side thereof in the drawing) and through a majority of a region of the solar cell 22 of interest (its left side in the drawing), with a given gap 25 from the underside electrode 24 of the adjacent solar cell 22. Likewise in the solar cell 30 as in the solar cells 22, the underside electrode 24 is formed on the surface of the conductive layer 32 and the insulation layer 14 so that the underside electrode 24 extends from a region at one end (a part on the right side in the drawing) of an adjacent solar cell 22 (that on the left side in the drawing) through a majority of the grounding solar cell 30 (the left side in the drawing), with a given gap 25 from the rear electrode 24 of the adjacent solar cell 22. The most part of the underside electrode 24 of the grounding solar cell 30 is located on the conductive layer 32.

The photoelectric conversion layers 26 of the solar cells (referred to as battery cells below) 22 and the grounding solar cell 30 (referred to simply as battery cell below) 30 are formed on the underside electrodes 24 so as to fill the gaps 25 between the adjacent underside electrodes 24. Therefore, the photoelectric conversion layers 26 are in direct contact with the insulation layers 14 and/or conductive layer 32 at the gaps 25.

Each photoelectric conversion layer 26 has a groove 27 extending from an adjacent battery cell 22 or 30 and reaching the underside electrode 24. Thus, each groove 27 is formed at a different position than the gap 25 located between adjacent underside electrodes 24.

The transparent electrodes 28 are formed on the surface of the photoelectric conversion layers 26 in such a manner as to fill the grooves 27 of the photoelectric conversion layers 26. Accordingly, each transparent electrode 28 is in direct contact and therefore electrically connected with the underside electrode 24 of an adjacent battery cell 22 or 30 at the groove 27. Thus, two adjacent battery cells 22 and adjacent battery cells 22 and 30 are connected in series.

Further, an opening 29 reaching the underside electrode 24 is formed between the transparent electrode 28 and the photoelectric conversion layer 26 of the battery cells 22 or the battery cell 30 on the one hand and the transparent electrode 28 and the photoelectric conversion layer 26 of the adjacent battery cells 22 or the battery cell 30 on the other hand. Thus, two adjacent battery cells 22 or adjacent battery cells 22 and 30 are separated by the opening 29.

As described above, serial connection of the battery cells 22 and 30 is established as the transparent electrode 28 of a battery cell 22 or 30 is connected with the underside electrode 24 of an adjacent battery cell 22 or 30.

In the solar cell module 10 illustrated in FIG. 2 according to this embodiment, the underside electrode 24 of the battery cell 22 at one extreme end (leftmost end in the drawing) has a lead wire in the form of a copper ribbon or the like, not shown, attached thereto to provide a positive (+) terminal, and the transparent electrode 28 of the battery cell 22 at the other extreme end (rightmost end in the drawing) has a like lead wire attached thereto to provide a negative (−) terminal whereas the underside electrode 24 of the central or substantially central battery cell 30 is grounded through electrical connection to the metal substrate 12, which is grounded through the conductive layer 30. The metal substrate 12 is connected through a like lead wire to a ground terminal.

The battery cells 22 and 30 each have the shape of a linear strip extending parallel to each other along one side of the rectangular metal substrate 12 in the direction normal to the cross section illustrated in FIG. 2 (the direction normal to the FIG. 2 drawing). Accordingly, the underside electrodes 24 and the transparent electrodes 28 are also electrodes in the form of a strip that is long in the direction parallel to the one side of the metal substrate 12.

The solar cells (photoelectric conversion devices) 22 according to this embodiment are integrated type CIGS solar cells (CIGS photoelectric conversion devices) and have a configuration such that the underside electrodes 24 are molybdenum electrodes, the photoelectric conversion layers 26 are made of CIGS, and the transparent electrodes 28 are made of ZnO. The buffer layers, when provided, are made of CdS. The grounding solar cell 30 has a similar configuration.

The solar cells 22 and 30 may be fabricated by any of known methods used to fabricate CIGS solar cells. One may use a laser scribing method or a mechanical scribing method to form the linear recesses such as the gaps 25 between the underside electrodes 24, the grooves 27 formed in the photoelectric conversion layers 26 and reaching the underside electrodes 24, and the openings 29 reaching the underside electrodes 24 and separating each block of a photoelectric conversion layer 26 and a transparent electrode 28 from adjacent blocks of a photoelectric conversion layer 26 and a transparent electrode 28.

Upon light entering the battery cells 22 and 30 from the side bearing the transparent electrodes 28 in the solar cell module 10 of the invention, the light passes through the transparent electrodes 28 and the buffer layers (not shown) and reaches the photoelectric conversion layers 26 to generate electromotive force, thus producing a current flowing, for example, from the transparent electrodes 28 to the underside electrodes 24. Note that the arrows shown in FIG. 2 indicate the direction of the current, and the direction in which electrons move is opposite to that of the current. Accordingly, the underside electrode 24 of the leftmost battery cell 22 in FIG. 2 has the positive (plus or +) polarity and the underside electrode 24 of the rightmost battery cell 22 has the negative (minus or −) polarity.

Now, components of the battery cells 22 and 30 forming the power generation layers 20 will be described.

The underside electrodes 24 and the transparent electrodes 28 in the solar cells 22 and 30 are provided both to harvest current generated by the photoelectric conversion layers 26. Both the underside electrodes 24 and the transparent electrodes 28 are each made of a conductive material. The transparent electrodes 28, provided on the side from which light is admitted, need to be pervious to light.

The underside electrodes 24 are formed of Mo, Cr or W, or a material composed of two or more of these. The underside electrodes 24 may have a single-layer structure or a laminated structure such as a dual-layer structure.

The underside electrodes 24 preferably have a thickness of 100 nm or more and more preferably 0.45 μm to 1.0 μm.

The underside electrodes 24 may be formed by any of vapor-phase film deposition methods as appropriate such as electron-beam deposition and sputtering.

The transparent electrodes 28 are formed, for example, of ZnO, ITO (indium tin oxide), or SnO₂, or a material composed of two or more of these. The transparent electrodes 28 may have a single-layer structure or a laminated structure such as a dual-layer structure. The thickness of the transparent electrodes 28, which is not specifically limited, is preferably 0.3 μm to 1 μm.

The transparent electrodes 28 may be formed by any of vapor-phase film deposition methods as appropriate such as electron-beam deposition and sputtering.

An anti-reflection film such as one made of MgF₂ may be formed on the transparent electrodes 28.

The buffer layers are provided to protect the photoelectric conversion layers 26 when forming the transparent electrodes 28 and allow the light passing through the transparent electrodes 28 to enter the photoelectric conversion layers 26.

The buffer layers are formed, for example, of CdS, ZnS, ZnO, ZnMgO, or ZnS (O, OH) or a material composed of two or more of these.

The buffer layers preferably have a thickness of 0.03 μm to 0.1 μm. The buffer layers are formed by any of appropriate methods including the chemical bath deposition (CBD) method and the solution growth method.

There may be provided a high-resistance film formed of, for example, ZnO between the buffer layers made of, for example, CBD-CdS and the transparent electrodes 28 made of, for example, ZnO:Al.

The photoelectric conversion layers 26 absorb the incoming light from the transparent electrodes 28 through the buffer layers to generate current. According to this embodiment, the photoelectric conversion layers 26 are not specifically limited in configuration; they are preferably formed of a compound semiconductor having, for example, at least one kind of chalcopyrite structure. The photoelectric conversion layers 26 may be formed of at least one kind of compound semiconductor composed of a Ib group element, a IIIb group element, and a VIb group element.

For a high optical absorptance and a high photoelectric conversion efficiency, the photoelectric conversion layers 26 are preferably formed of at least one kind of compound semiconductor composed of at least one kind of Ib group element selected from the group consisting of Cu and Ag, at least one kind of IIIb group element selected from the group consisting of Al, Ga, and In, and at least one kind of VIb group element selected from the group consisting of S, Se, and Te. The compound semiconductor is exemplified by CuAlS₂, CuGaS₂, CuInS₂, CuAlSe₂, CuGaSe₂, CuInSe₂(CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGax)Se₂(CIGS), Cu(In₁₋ₓAlₓ)Se₂, Cu(In₁₋ₓGaₓ)(S, Se)₂, Ag(In₁₋ₓGaₓ)Se₂, and Ag(In₁₋ₓGaₓ)(S, Se)₂.

The photoelectric conversion layers 26 preferably contain CuInSe₂(CIS) and/or Cu(In,Ga)Se₂(CIGS), which is obtained by dissolving Ga in the former. CIS and CIGS are semiconductors each having a chalcopyrite crystal structure and reportedly have a high optical absorptance and a high photoelectric conversion efficiency. Further, CIS and CIGS have an excellent durability such that they are less liable to decrease in efficiency through exposure to light or other causes.

The photoelectric conversion layers 26 contain impurities for obtaining a desired semiconductor conductivity type. Impurities may be added to the photoelectric conversion layers 26 by diffusion from adjacent layers and/or direct doping into the photoelectric conversion layers 26. The photoelectric conversion layers 26 permit presence therein of a component element of I-III-VI group semiconductor and/or a density distribution of impurities; the photoelectric conversion layers 26 may contain a plurality of layer regions formed of materials having different semiconductor properties such as n-type, p-type, and i-type.

For example, a CIGS semiconductor, when given a thickness-wise distribution of Ga amount in the photoelectric conversion layers 26, permits control of band gap width, carrier mobility, etc. and thus achieves a high photoelectric conversion efficiency.

The photoelectric conversion layers 26 may contain single or two or more kinds of semiconductors other than I-III-VI group semiconductors. Such semiconductors other than I-III-VI group semiconductors include a semiconductor formed of a IVb group element such as Si (IV group semiconductor), a semiconductor formed of a IIIb group element such as GaAs and a Vb group element (III-V group semiconductor), and a semiconductor formed of a IIb group element such as CdTe and a VIb group element (II-VI group semiconductor). The photoelectric conversion layers 26 may contain any other component than a semiconductor and impurities used to obtain a desired conductivity type, provided that no detrimental effects are thereby produced on the properties.

The photoelectric conversion layers 26 may contain a I-III-VI group semiconductor in any amount as deemed appropriate. The ratio of a I-III-VI group semiconductor contained in the photoelectric conversion layers 26 is preferably 75 mass % or more and, more preferably, 95 mass % or more and, most preferably, 99 mass % or more.

According to this embodiment, when the photoelectric conversion layers 26 are CIGS layers, the CIGS layers may be formed by such known film deposition methods as 1) multi-source evaporation methods, 2) selenization method (selenization/sulfidization method), 3) sputtering method, 4) hybrid sputtering method, and 5) mechanochemical processing method.

1) Known multi-source evaporation methods include: three-stage method (J. R. Tuttle et al, Mat. Res. Soc. Symp. Proc., Vol. 426 (1966), p. 143, etc.) and a simultaneous evaporation method by EC group (L. Stolt et al.: Proc. 13th ECPVSEC (1995, Nice) 1451, etc.).

According to the first-mentioned three-phase method, firstly, In, Ga, and Se are simultaneously evaporated under high vacuum at a substrate temperature of 300° C., which is then increased to 500° C. to 560° C. to simultaneously vapor-deposit Cu and Se, whereupon In, Ga, and Se are vapor-deposited. According to the latter method or the simultaneous evaporation method by EC group, Cu excess CIGS is vapor-deposited in an earlier stage of vapor deposition, and In excess CIGS is vapor-deposited in a later stage.

Following methods are among those where improvements have been made on the above methods to improve crystallinity of CIGS films.

a) Method using ionized Ga (H. Miyazaki et al, phys. stat. sol. (a), Vol. 203 (2006), p. 2603, etc.)
b) Method using cracked Se (a pre-printed collection of speeches given at the 68th Academic Lecture by Japan Society of Applied Physics) (autumn of 2007, Hokkaido Kogyo Univ.), 7P-L-6, etc.)
c) Method using cracked Se (a pre-printed collection of speeches given at the 54th Academic Lecture by Japan Society of Applied Physics) (spring of 2007, Aoyama Gakuin Univ.), 29P-ZW-14, etc.), and
d) Method using light excitation process (a pre-printed collection of speeches given at the 54th Academic Lecture by Japan Society of Applied Physics) (spring of 2007, Aoyama Gakuin Univ.), 29P-ZW-14, etc.).

2) The selenization method is also called two-stage method, whereby firstly a metal precursor formed of a laminated film such as a Cu layer/In layer, a (Cu—Ga) layer/In layer, or the like is formed by sputter deposition, vapor deposition, or electrodeposition, and the film thus formed is heated in selenium vapor or hydrogen selenide to a temperature of 450° C. to 550° C. to produce a selenide such as Cu(In₁₋ₓGax)Se₂ by thermal diffusion reaction. This method is called vapor-phase selenization method. Another method available for the purpose is the solid-phase selenization method whereby solid-phase selenium is disposed on a metal precursor film to achieve selenization by solid-phase diffusion reaction using the solid-phase selenium as selenium source.

The selenization method may be implemented in several ways: selenium is previously mixed in a given ratio into the metal precursor film to avoid abrupt volume expansion that might take place in selenization process (T. Nakada et al, Solar Energy Materials and Solar Cells 35 (1994) 204-214, etc.); or selenium is sandwiched between thin metal films (e.g., as in Cu layer/In layer/Se layer . . . Cu layer/In layer/Se layer) to form a multiple-layer precursor film (T. Nakada et al, Proc. of 10th European Photovoltaic Solar Energy Conference (1991) 887-890, etc.).

Among the methods of forming a graded band gap CIGS film is one whereby firstly a Cu—Ga alloy film is disposed, and an In film is disposed thereon, subsequently achieving selenization by inclining the Ga density in the film thickness direction using natural thermal diffusion (K. Kushiya et al, Tech Digest 9th Photovoltaic Scienece and Engineering Conf. Miyazaki, 1996 (Intn. PVSEC-9, Tokyo, 1996) p. 149, etc.)

3) Known sputter deposition techniques include: one using CuInSe₂ polycrystal as a target, one called two-source sputter deposition using H₂Se/Ar mixed gas as sputter gas (J. H. Ermer, et al, Proc. 18th IEEE Photovoltaic Specialists Conf. (1985) 1655-1658, etc.) and one called three-source sputter deposition whereby a Cu target, an In target, and an Se or CuSe target are sputtered in Ar gas (T. Nakada, et al, Jpn. J. Appl. Phys. 32 (1993) L1169-L1172, etc.).

4) Known hybrid sputter deposition methods include one whereby metals Cu and In are subjected to direct current sputtering, while only Se is vapor-deposited (T. Nakada, et al., Jpn. Appl. Phys. 34 (1995) 4715-4721, etc.).

5) The mechanochemical processing method is a method whereby a material selected according to the CIGS composition is placed in a planetary ball mill container and mixed by mechanical energy to obtain pulverized CIGS, which is then applied to a substrate by screen printing and annealed to obtain a CIGS film (T. Wada et al, Phys. stat. sol. (a), Vol. 203 (2006) p. 2593, etc.).

Other methods of forming a CIGS film include screen printing method, close-spaced sublimation method, MOCVD method, and spray method. For example, the screen printing method or the spray method may be used to form a fine-particle film containing a Ib group element, a IIIb group element, and a VI group element on a substrate and obtain a crystal having a desired composition by, for example, pyrolysis treatment (which may be a pyrolysis treatment carried out under a VIb group element atmosphere) (JP 9-74065 A, JP 9-74213 A, etc.).

Although the solar cells 22 and 30 of the solar cell module 10 according to the embodiment described above are integrated CIGS solar cells, the invention is not limited thereto. The solar cells of solar cell modules according to the invention (photoelectric conversion device, particularly the photoelectric conversion layers formed thereof) may, for example, be amorphous silicon (a-Si) based solar cells, tandem structure solar cells (a-Si/a-SiGe tandem structure solar cells), series-connected structure (SCAF) solar cells (a-Si series-connected structure solar cells), CdTe (cadmium telluride) based solar cells, thin-film silicon solar cells, dye-sensitized solar cells, organic solar cells, substrate type solar cells, or superstrate type solar cells.

Although the solar cell module 10 according to the embodiment illustrated in FIG. 2 has a positive polarity (plus polarity) on the side where the underside electrodes 24 are located and a negative polarity (minus polarity) on the side where the transparent electrodes 28 are located, the invention is not limited thereto. Depending upon the solar cells, the solar cell module 10 may have a positive polarity (plus polarity) on the side where the transparent electrodes 28 are located and a negative polarity (minus polarity) on the side where the underside electrodes 24 are located.

For example, where the solar cells 22 and 30 are formed of tandem structure solar cells (a-Si/a-SiGe tandem structure solar cells), one may use a configuration such that, for example, each underside electrode 24 is an electrode having a laminated Ag (silver)/ZnO layer structure, each transparent electrode 28 is formed of ITO, each photoelectric conversion layers 26 is formed, for example, of a laminated layer structure comprising an n-type semiconductor layer, an intrinsic semiconductor layer such as a small-crystal silicone layer and an amorphous silicon germanium (a-SiGe) layer, and a p-type semiconductor layer disposed on each other, further comprising disposed thereon an n-type semiconductor layer, an intrinsic semiconductor layer such as an amorphous silicon layer (a-Si), and a p-type semiconductor layer.

Where the solar cells 22 and 30 are formed of CdTe based solar cells, each photoelectric conversion layer 26 may be formed, for example, of a photoelectric conversion layer of a so-called CdTe (cadmium telluride) type.

Next, the conductive layer 32 of the grounding solar cell 30 will be described.

The conductive layer 32, which is the most characteristic feature of the invention, is disposed in lieu of the insulation layer 14 between the metal substrate 12 and the underside electrode 24 in the grounding solar cell 30. The conductive layer 32 is conductive and electrically connects the underside electrode 24 to the metal substrate 12, which is grounded, to permit electric conduction between them and thus ground the underside electrode 24.

The conductive layer 32 is formed by a mixture of components of the metal substrate 12, the insulation layer 14, and the underside electrode 24 to assume a conductive property.

In the example illustrated in FIG. 2, the conductive layer 32 is formed beneath and only within the underside electrode 24 of the grounding solar cell 30 and not formed beneath the gap 25, thus leaving the insulation layer 14 at the gap 25. The invention is not limited to such a configuration, however. The conductive layer 32 may be formed to extend also beneath the gap 25 and the underside electrode 24 of an adjacent solar cell 22, provided that the conductive layer 32 is contained within the grounding solar cell 30. In this case, the underside electrode 24 of the grounding solar cell 30 and the underside electrode 24 of an adjacent solar cell 24 are short-circuited so that the grounding solar cell 30 does not contribute to power generation.

Such a conductive layer 32 may, for example, be formed as follows: the conventional solar cell module 50 illustrated in FIG. 7 is fabricated; an ultrasonic solder 34 is then applied to the transparent electrode 28 of the solar cell 22 of which the grounding solar cell 30 is to be formed as illustrated in FIG. 3; the thermal ultrasonic treatment is given only to the solar cell 22 coated with the ultrasonic solder 34 to achieve electrical breakdown in the insulation layer 14 corresponding to the section of the solar cell 22 coated with the ultrasonic solder 34 and melt and mix the surfaces of the metal substrate 12 and the underside electrode 24 that were in contact with the insulation layer 14 where electrical insulation has broken down, thus bringing the metal substrate 12, the underside electrode 24, and the broken-down insulation layer 14 into a state of mixture. The creation of the state of mixture of the conductive layer 14, while not made clear, is assumed to take place as follows: for example, the thermal ultrasonic treatment given only to the solar cell 22 coated with the ultrasonic solder 34 achieves electrical breakdown in the insulation layer 14 corresponding to the section of the solar cell 22 coated with the ultrasonic solder 34 to produce small gaps and create a state of porousness, while melting the surfaces of the metal substrate 12 and the underside electrode 24 that were in contact with the broken-down insulation layer 14 to allow the melt to enter the small gaps formed in the broken-down insulation layer 14. Where the transparent electrode 28 and the photoelectric conversion layer 26 of the grounding solar cell 30 are also broken down, the conductive layer 32 formed may also contain therein mixed these and the ultrasonic solder 34. The solder may be applied over the whole cell or, as illustrated in FIG. 3, the transparent electrode 28 may be left exposed on one side or on both sides. Rather than by spreading, solder may be linearly supplied on the cell and melted as it is deposited. From a viewpoint of manufacture, however, it is preferable that linearly deposited solder is applied simultaneously after deposit, or soldering is effected simultaneously in a plurality of linear deposits.

The conductivity of the conductive layer 32 thus formed may be assumed to depend upon the state of mixture of the conductive layer 32. Accordingly, the conductivity of the conductive layer 32 may be controlled and a required conductivity may be obtained by appropriately controlling the amount of the ultrasonic solder 34 applied and, in the thermal ultrasonic treatment, the temperature of heat applied, the time during which the heat is applied, the magnitude of ultrasonic wave applied, and the length of time of the thermal ultrasonic treatment, according to the configuration and functions of the solar cell 22 of which the grounding solar cell 30 is to be formed as well as the necessity of power generation function, etc., especially the thickness of the insulation layer 14.

One may carry out experiments, simulations, and the like to predetermine: the relationships between the conductivity of the conductive layer 32; the configuration and functions of the solar cell 22, especially the thickness of the insulation layer 14, etc.; and the amount of the ultrasonic solder 34 applied, the temperature of heat applied in the thermal ultrasonic treatment, the time during which the heat is applied, the magnitude of ultrasonic wave applied, and the length of time of the thermal ultrasonic treatment.

In the above example, the conductive layer 32 is formed after the conventional solar cell module 50 is completed as illustrated in FIG. 7, but the invention is not limited this way. The conductive layer 32 may be formed at any stage of the solar cell module fabrication process, provided that the insulation layer 14 is formed on the metal substrate 12.

The solar cell module may be fabricated, for example, in such a sequence that the ultrasonic solder 34 is applied to a given section of a solar cell, of which the grounding solar cell 30 is to be formed, on the insulation layer 14 on the metal substrate 12, followed by thermal ultrasonic treatment to form the conductive layer 32 where the broken-down insulation layer 14, the metal substrate 12, and the ultrasonic solder 34 are mixed, whereupon a plurality of solar cells 22 and the grounding solar cell 30 may be formed. Alternatively, one may follow a sequence such that the ultrasonic solder 34 is applied to the underside electrode 24 of a given section of a solar cell, of which the grounding solar cell 30 is to be formed, after the underside electrode 24 is formed on the insulation layer 14 on the metal substrate 12, followed by thermal ultrasonic treatment to form the conductive layer 32 where the broken-down insulation layer 14, the metal substrate 12, the underside electrode 24, and, optionally, the ultrasonic solder 34 are mixed, whereupon the photoelectric conversion layer 26 and the transparent electrode 28 are thereon formed sequentially, thereby to form a plurality of solar cells 22 and the grounding solar cell 30. Alternatively, the conductive layer 32 may be likewise formed after forming the photoelectric conversion layer 26, followed by formation thereon of the transparent electrode 28, whereupon a plurality of solar cells 22 and the grounding solar cell 30 may be thereon formed.

According to any of these methods, the solar cells 22 are completed after the conductive layer 32 is formed and, therefore, at least one of the underside electrode 24, the photoelectric conversion layer 26, and the transparent electrode 28 needs to be formed, which requires accurate alignment. Thus, the conductive layer 32 is formed preferably after the solar cells 22 are formed.

The solar cell module according to the first embodiment of the invention is configured basically as described above and is fabricated as follows.

FIG. 4 is a flow chart illustrating an example of method for manufacturing the solar cell module according to the first embodiment of the invention illustrated in FIG. 2.

As illustrated in FIG. 4, an aluminum substrate is used to form the metal substrate 12, which is subjected to anodization processing by the method described above to form an anodized film that serves as the insulation layer 14 on the surface so that an aluminum substrate having an anodized film is formed, thus providing the support substrate 16 (step S100).

Needless to say, the support substrate 16 may be an aluminum substrate previously provided with an anodized film.

Next, a Mo film is formed on the insulation layer 14 of the support substrate 16 by any of known film deposition methods described above such as DC magnetron sputtering technique (step S102).

Next, the Mo film thus formed on the insulation layer 14 is cut by the laser scribing method described above and patterned to a pattern 1 to form the gaps 25 and the underside electrodes (step S104).

Then, CIGS based compound semiconductor films (p-type CIGS based light absorption films), which serve as the photoelectric conversion layers 26, are formed on the underside electrodes 24 formed on the insulation layers 14 by any of the known methods described above such as the selenization/sulfidization method or a multi-source evaporation method in such a manner as to fill the gaps 25 (step S106).

Subsequently, CdS films that are to serve as buffer layers (n-type high-resistance buffer layers) are formed on the thus formed CIGS based compound semiconductor films by any of the known methods described above such as the CBD technique (step S108).

Next, the CIGS based compound semiconductor films and the CdS films thus formed on the underside electrodes 24 are cut as a whole by the mechanical scribing method described above and patterned to a pattern 2 to form the grooves 27 reaching the underside electrodes 24 thereby to form the photoelectric conversion layers 26 and the buffer layers (step S110).

Then, ZnO films (n-type ZnO transparent conductive film window layer), of which the transparent electrode layer 28 is to be made, are formed by any of the known methods described above such as the MOCVD method or RF sputtering method on the thus formed buffer layers (photoelectric conversion layers 26) in such a manner as to fill the grooves 27 (step S112).

Next, the ZnO films, the buffer layers, and the photoelectric conversion layers thus formed are cut as a whole by the mechanical scribing method described above and patterned to a pattern 3 to form openings 29 reaching the underside electrodes 24 between adjacent solar cells 22 and separately provide the photoelectric conversion layer 26, the buffer layer, and the transparent electrode layer 28 in each solar cell 22, thereby forming a plurality of solar cells 22 (step S114).

Then, the ultrasonic solder 34 is applied onto the transparent electrode layer 28 of a solar cell 22 previously allocated to form the grounding solar cell 30 (step S116). Next, the transparent electrode layer 28 of the solar cell 22 coated with the ultrasonic solder 34 is selectively subjected to thermal ultrasonic treatment to achieve electrical breakdown in its insulation layer 14 and mix the components of the metal substrate 12 and those of the underside electrode 24 and form the conductive layer 32 (step S118).

Thus, the solar cell module 10 according to the first embodiment is formed (step S118).

Next, we will describe a second embodiment of the solar cell module according to the invention.

FIG. 5 is a cross section schematically illustrating the second embodiment of the solar cell module according to the invention.

The second embodiment of the solar cell module 40 illustrated in FIG. 5 has the same configuration as the first embodiment of the solar cell module illustrated in FIG. 2 except that a conductive layer 42 of the grounding solar cell 30 has a different configuration. Thus, like components are given like reference characters, and a detailed description thereof will be omitted.

In a solar cell module 40 according to the second embodiment as illustrated in FIG. 5, the underside electrode 24 extending from a neighboring solar cell 22 is disposed directly between the metal substrate 12 and the photoelectric conversion layer 26 to form the conductive layer 42 in lieu of the conductive layer 32 of the grounding solar cell 30 of the solar cell module 10 according to the first embodiment. Since the underside electrode 24 and the grounded metal substrate 12 are thus in direct contact and electrically connected with each other in the solar cell module 40, the underside electrode 24 of the grounding solar cell 30 can be grounded through the metal substrate 12.

Thus, the solar cells 22 and 30 of the solar cell module 40 according to the second embodiment may of course have any configurations as appropriate (photoelectric conversion device, photoelectric conversion layer) as may the solar cell module 10 described above.

The solar cell module 40 comprising such a conductive layer 42 may be configured using the support substrate 16 that is not provided with the insulation layer 14, such as an anodized film, in an area corresponding to the grounding solar cell 30 but provided with the insulation layer 14, such as an anodized film, in the other area, following a procedure of forming the power generation layer 20, that is, the underside electrode 24 and the conductive layer 42, the photoelectric conversion layer 26 and the buffer layer, and the transparent electrode layer 28 in this order, to form a plurality of solar cells 22 and the grounding solar cell 30 as in the case of the solar cell module 10 according to the first embodiment described above. This is how the solar cell module 40 according to the second embodiment is formed.

In lieu of the support substrate 16 including the metal substrate 12 that is not provided with the insulation layer 14 in the region corresponding to the grounding solar cell 30, one may use the support substrate 16 where the insulation layer 14 is formed over the whole surface of the metal substrate 12 such as an anodized aluminum substrate, and where a part of the insulation layer 14 such as an anodized film located in a region corresponding to the grounding solar cell 30 is removed by scribing, etching, or other means, and likewise form the power generation layer 20 by a process starting with vapor deposition of the underside electrode 24 to construct the solar cell module 40 according to the second embodiment.

The first and second embodiments of the solar cell modules 10 and 40 thus achieve dividing the potential difference (voltage) between the solar cell 22a located at one end (on the left-hand side in FIGS. 2 and 5) and the solar cell 22b located at the other end (on the right-hand side in FIGS. 2 and 5) to two approximately half potential differences, one (plus voltage) between the solar cell 22a and the grounding solar cell 30 and the other (minus voltage) between the solar cell 22b and the grounding solar cell 30, and, hence, achieve reducing the potential difference at the metal substrate 12 to about a half of the output voltage by electrically connecting the underside electrode 24 of the grounding solar cell 30 located at the center or substantially at the center of the array of solar cells 22 to the metal substrate 12 of the support substrate 16 and by grounding the metal substrate 12.

Thus, the present invention permits minimizing the adverse effects produced by the stray capacitance generated between the power generation layer 20 of the solar cells 22 and the metal substrate 12, minimizing the potential difference between them, eliminating the need to increase the withstand voltage of the insulation layer 14 between the power generation layer 20 and the metal substrate 12, and increasing the output voltage per module, thereby providing the solar cell modules 10 and 40 capable of generating high voltages.

The solar cell module 10 or 40 of the invention, when provided, for example, with 461 solar cells 22, the solar cell 22 located at the center being adapted to act as the grounding solar cell 30, is capable of generating an output of ±150 V, and may be connected to a 2-phase inverter or 3-phase inverter of a PWM type (pulse-width modulation type) to convert direct current to 2-phase alternating current or 3-phase alternating current and harvest 2-phase alternating current electricity or 3-phase alternating current electricity.

The solar cell modules 10 and 40 according to the first and second embodiment of the invention may be used in solar photovoltaic power generation systems.

FIG. 6 schematically illustrates an example of configuration of a solar photovoltaic system using the solar cell module of the invention. A solar photovoltaic system 60 illustrated in FIG. 6 uses the solar cell module 10 illustrated in FIG. 2 as a representative example of the solar cell module. One may use the solar cell module 40 illustrated in FIG. 5 instead.

As illustrated in FIG. 6, the solar photovoltaic power generation system 60 comprises the solar cell module 10, an inverter 62, an interconnection switch 64, a circuit breaker 66, an alternating current electricity system 68 such as a commercial alternating current electricity system, and a user load 70.

In the solar photovoltaic power generation system 60, the output of the solar cell module 10 is connected to the input of the inverter 62, whose output is connected through the interconnection switch 64 to the line extending from the alternating current electricity system 68 and is connected through the circuit breaker 66 to the user load 70 to ensure that the output electricity of the solar cell module 10 is delivered to the user load 70 and the alternating current electricity system 68. Thus, in the solar photovoltaic power generation system 60, the solar cell module 10 is capable of an interconnected operation with the alternating current electricity system 68.

The circuit breaker 66 may be a ground fault interrupter such as an earth leakage breaker. A ground fault interrupter such as an earth leakage breaker or a circuit breaker may be used in lieu of the interconnection switch 64.

The inverter 62 is connected to the solar cell module 10 to convert the direct current generated by the solar cell module 10 to alternating current; it may be an uninsulated transformerless inverter. The inverter 62 may be a 2-phase inverter or 3-phase inverter of a PWM (pulse-width modulation) type. The solar cell module 10 has three output terminals: a positive terminal (+), a negative terminal (−), and a ground terminal. The three output terminals are connected to the input terminals of the inverter 62 so that the neutral point of the inverter 62 coincides with the ground of the solar cell module 10.

Thus, the solar photovoltaic power generation system 60 permits use of an uninsulated inverter such as an inexpensive transformerless inverter without requiring such components as potential fixing means and switching devices as did conventional solar photovoltaic power generation apparatuses, and without requiring a circuit breaker, such as a ground fault interrupter, having a specially low sensitivity, and can produce a high-voltage output owing to the solar cell module that may be used in an unlimited number as a unit solar battery.

The solar cell module of the invention is configured as described above.

While the solar cell module of the invention has been described above in detail with reference to various embodiments, the present invention is by no means limited to those embodiments, and various improvements or design modifications may be made without departing from the scope and spirit of the present invention.

What is claimed is:

1. A solar cell module comprising
a metal substrate,
an insulation layer formed on the metal substrate, series-connected solar cells formed on the insulation layer,
two output terminals provided on both ends of the solar cells, and
a grounding terminal connected to a central portion of the solar cells,
wherein each of said solar cells comprise
an underside electrode formed on the insulation layer,
a photoelectric conversion layer provided on the underside electrode to convert received light into electricity, and
a transparent electrode layer formed on the photoelectric conversion layer, and
wherein said transparent electrode layer of each of the solar cells is connected to the underside electrodes of adjacent solar cell to connect the solar cells in series, and
wherein said two output terminals are each composed of a first output terminal connected to the underside electrode of a solar cell at one end of the solar cells and a second output terminal connected to the underside electrode of a solar cell at the other end of the solar cells, and
wherein said solar cell module further comprises an electrical conductive layer provided to electrically connect the metal substrate to the underside electrode of one grounding solar cell located in a position in a range of from plus 10% to minus 10% of the number of the solar cells from a solar cell located at a center of the solar cells, and
wherein said ground terminal is connected to the metal substrate and further connected through the metal substrate and the conductive layer to the grounding solar cell.

2. The solar cell module according to claim 1, wherein said grounding solar cell is a solar cell located in a position in a range of from plus 5% to minus 5% of the number of the solar cells from the solar cell located at the center.

3. The solar cell module according to claim 1, wherein said grounding solar cell is the solar cell located at the center.

4. The solar cell module according to claim 1, wherein said conductive layer is a part of the insulation layer where insulation has broken down and which is rendered electrically conductive by subjecting the part of the insulation layer on the metal substrate of the grounding solar cell to thermal ultrasonic treatment to achieve electrical breakdown in the part of the insulation layer.

5. The solar cell module according to claim 1, wherein the conductive layer is a part of the insulation layer where insulation has broken down and which is rendered electrically conductive by forming at least the underside electrode on the insulation layer on the metal substrate to at least partially form the grounding solar cell, applying ultrasonic solder to the grounding solar cell at least partially formed and then subjecting to thermal ultrasonic treatment the part of the insulation layer on the metal substrate of the grounding solar cell at least partially formed where the ultrasonic solder has been applied to achieve electrical breakdown in the part of the insulation layer.

6. The solar cell module according to claim 1, wherein the conductive layer is a part of the insulation layer where insulation has broken down and which is rendered electrically conductive by forming the solar cells, applying ultrasonic solder to the grounding solar cell and then subjecting to thermal ultrasonic treatment the part of the insulation layer on the metal substrate of the grounding solar cell where the ultrasonic solder has been applied to achieve electrical breakdown in the part of the insulation layer.

7. The solar cell module according to claim 1, wherein the conductive layer is the underside electrode layer of the grounding solar cell formed on an exposed part of the metal substrate by forming the insulation layer on the metal substrate, removing a part of the insulation layer corresponding to the grounding solar cell to expose the metal substrate, and then forming the underside electrode on the insulation layer and the exposed part of the metal substrate.

8. The solar cell module according to claim 1, wherein the solar cells are separated each other by linear grooves and each of the solar cells are formed into a linear form on the insulation layer on the metal substrate, and wherein the underside electrode, the photoelectric conversion layer, the transparent electrode layer, and the conductive layer have a linear shape.

9. The solar cell module according to claim 1, wherein the solar cells are integrated thin-film solar cells.

10. The solar cell module according to claim 1, wherein the solar cells comprise one kind of thin-film solar cells selected from the group consisting of CIS based thin-film solar cells, CIGS based thin-film solar cells, silicon-based thin-film solar cells, CdTe based thin-film solar cells, III-V group based thin-film solar cells, dye-sensitized thin-film solar cells, and organic thin-film solar cells.

11. The solar cell module according to claim 1, wherein the photoelectric conversion layer comprises as a major component at least one kind of a compound semiconductor having chalcopyrite structure.

12. The solar cell module according to claim 11, wherein the photoelectric conversion layer comprises as a major component at least one kind of compound semiconductor containing an Ib group element, a IIIb group element, and a VIb group element.

13. The solar cell module according to claim 12, wherein the photoelectric conversion layer comprises as a major component at least one kind of compound semiconductor containing
at least one kind of Ib group element selected from the group consisting of Cu and Ag,
at least one kind of IIIb group element selected from the group consisting of Al, Ga, and In, and
at least one kind of VIb group element selected from the group consisting of S, Se, and Te.

14. The solar cell module according to claim 1, wherein the metal substrate having the insulation layer formed thereon is formed of an anodized aluminum substrate, and the insulation layer is an anodized film.

15. The solar cell module according to claim 14, wherein the aluminum substrate is a composite aluminum substrate made of a composite material.

16. The solar cell module according to claim 15, wherein the aluminum substrate is a clad sheet formed of a steel sheet sandwiched by two aluminum sheets or a clad sheet formed of a stainless steel sheet and an aluminum sheet.
